(19) United States
(12) Patent Application Publication
(10) Pub. No.: US 2024/0431069 A1
(43) Pub. Date: Dec. 26, 2024

(54) FAN CONTROL FOR POWER OVER ETHERNET DEVICE BASED ON POWER USAGE

(71) Applicant: HEWLETT PACKARD ENTERPRISE DEVELOPMENT LP, Spring, TX (US)

(72) Inventor: Michael Robert Frith, Rancho Cordova, CA (US)

(21) Appl. No.: 18/340,491

(22) Filed: Jun. 23, 2023

(51) Int. Cl. H05K 7/20; G06F 1/20

(52) U.S. Cl. CPC H05K 7/20209; G06F 1/206; H05K 7/20172

(57) ABSTRACT

A power over ethernet (PoE) power sourcing equipment (PSE) includes PoE ports connectable via communications links to powered devices (PDs). The PSE also includes a power supply unit (PSU) that supplies PoE power to the PDs via the PoE ports and one or more fans that provide airflows through the PSE, including at least a first fan that provides an airflow to the PSU. The PSE also has control circuitry comprising fan control logic configured to monitor a PoE power usage parameter indicative of an amount of the PoE power supplied by the PSU. The fan control logic is also configured to control the speed of at least the first fan based at least in part on the PoE power usage parameter.

### INTRODUCTION

Networking devices, such as switches, routers, or access points, generally have ports into which communication cables can be removably connected to allow for data to be communicated through the networking device (e.g., between two client devices coupled to respective ports of the networking device). Examples of such ports include RJ45 ports, which may be connected to Ethernet cables. In particular, some networking devices may be capable of providing power-over-ethernet (PoE) on one or more of their ports, which allows for data signals and electrical power supply signals to be communicated over the same, single ethernet cable. This may allow a PoE-enabled electronic device to be communicably coupled to a network and to receive power via the same cable, which may provide more flexibility in how the device can be deployed (e.g., the device may no longer need to be positioned near a power outlet or have long power cables to reach such an outlet). In a PoE system, a device that provides the power to other devices via PoE is referred to as a Power Sourcing Equipment (PSE) and the devices that receive power from the PSE are referred to as Powered Devices (PD). The PSE generally also serves as a networking element, such as a switch or router. PDs may also be networking elements (e.g., a wireless access point, a PoE repeater/hub, etc.), network end points (e.g., a security camera, an internet-of-things (IoT) device, etc.), or any other electronic device with a PoE port.

### BRIEF DESCRIPTION OF THE DRAWINGS

The present disclosure can be understood from the following detailed description, either alone or together with the accompanying drawings. The drawings are included to provide a further understanding of the present disclosure and are incorporated in and constitute a part of this specification. The drawings illustrate one or more examples of the present teachings and together with the description explain certain principles and operation. In the drawings:

FIG. 1 is a block diagram illustrating an example PSE.

FIG. 2 is a block diagram illustrating a first example fan control logic.

FIG. 3 is a process flow chart illustrating a first example method performable by the first example fan control logic.

FIG. 4 is a schematic block diagram illustrating a first example circuit for implementing aspects of the first example method.

FIG. 5 is a table illustrating conditions, comparator outputs resulting from the conditions, and fan control schemes indicated by those comparator outputs.

FIG. 6 is a process flow chart illustrating a second example method performable by the second example fan control logic.

FIG. 7 is a schematic block diagram illustrating a second example circuit for implementing aspects of the second example method.

FIG. 8 is a table illustrating conditions, combinations of comparator outputs resulting from the conditions, and fan control schemes indicated by those combinations of comparator outputs.

FIG. 9 is a block diagram illustrating a second example fan control logic.

FIG. 10 is a process flow chart illustrating a third example method performable by the second example fan control logic.

FIG. 11 is a schematic block diagram illustrating a third example circuit.

FIG. 12 is a graph illustrating an example PoE power usage-based fan curve.

FIG. 13 is a block diagram illustrating an example computer program product.

### DETAILED DESCRIPTION

Electronic devices, such as a PSE, generate heat while powered up and in use. Consequently, such devices may be provided with one or more fans that are configured to flow air over the components of the device to dissipate the heat generated by the device and to cool its components. The more heat generated by the device, the more airflow may be required to keep the components within desired operating temperatures. However, providing too much airflow can also have undesired side effects in some cases, for example because higher fan speeds produce greater noise output and utilize more electrical power. The noise output can be quite high in some circumstances, to the point of potentially irritating users (this is particularly relevant for devices that are deployed in populated spaces, such as access points or other networking devices deployed in campuses or office buildings). Thus, it may be desirable in some circumstances to reduce unnecessary noise generation by providing only as much airflow as is needed to adequately cool the device. Moreover, because the amount heat generated by the components of a device may vary from time to time and from one component to the next, the amount of airflow that is needed will also change from time to time and may be different for each fan if more than one fan is present. Thus, some devices endeavor to dynamically change the speeds of their fans so as to keep the fan speeds as low as is feasible, thus reducing unnecessary noise, while still providing adequate cooling in view of the current thermal conditions.

One approach to dynamically controlling the fan speeds is to control the fan speed based on temperatures sensed at one or more locations within the device. For example, a fan controller may determine the fan speed set points by consulting a predetermined function, often referred to as a “fan curve,” which relates sensed temperatures as an independent variable to a fan speed set point as a dependent variable. The fan controller can periodically read the sensed temperature and then consult the fan curve to determine the next fan speed set point for the fan, and thus as thermal conditions in the device change this will be reflected in the sensed temperatures and the fan speeds can change accordingly.

But controlling fan speeds using temperature sensors and temperature-based fan curves (hereinafter “temperature-based fan control”) may not always be feasible or yield satisfactory results. In particular, not all PSE are equipped with temperature sensors, and in such a PSE that lacks temperature sensors the use of temperature-based fan control may not be possible. Moreover, even in those PSE that are equipped with temperature sensors, the sensed temperatures might be inadequate for setting optimal fan speeds for cooling all for the components of the PSE. In particular, the temperature sensors are generally arranged to sense temperatures of (or near) some components but not others. Because some components may have different thermal needs than others, the fan speed that that is best for the components whose temperature is sensed may not be optimal for other components whose temperatures are not sensed. Thus, a situation can arise in which the components whose temperatures are not being sensed may not receive adequate cooling (i.e., fans are driven at too low a speed) or may receive too much cooling (i.e., fans are driven at too high a speed, resulting in unnecessary noise generation).

For example, a PSE may have one or more temperature sensors arranged to sense the temperature of processing or other control circuitry (e.g., a processor, switching circuitry, etc.) of the PSE, but there may be no sensors that are arranged to sense a temperature of a power supply unit (PSU) of the PSE. The processor/control circuitry and the PSU can have very different thermal needs, as the amount of heat generated by one can be largely independent of the amount of heat generated by the other. More specifically, the amount of heat generated by the processing/control circuitry may depend largely on the amount of data communication passing through the PSE. In contrast, the amount of heat generated by the PSU may depend largely on how much PoE power is being supplied from the PSE to connected PDs. Thus, a situation can arise, for example, in which the processing/control circuitry is heavily loaded with many communications passing through the PSE, while simultaneously the PSU is providing little PoE power to PDs. In such a circumstance, the processing/control circuitry may be generating a lot of heat while the PSU is generating little heat. In this case, if traditional temperature-based fan control is used, the fans may be driven at a high speed because the temperature of the processing/control circuitry is high, but this high fan speed may be much more than is needed to cool the PSU, which is generating little heat. Thus, the fan that cools the PSU produces unnecessary noise because it is driven at a faster speed that is needed. Conversely, a situation can arise in which the PSU is providing much PoE power to PDs while simultaneously the processing circuitry is lightly loaded with communications. In this case, the PSU is generating much heat while the control circuitry is generating little heat. Thus, if traditional temperature-based fan control is used, the fans may be driven at a low speed because the temperature of the processing/control circuitry is low, but this fan speed may be too low for dissipating the high amount of heat being generated by the PSU. Thus, the PSU may be inadequately cooled (its temperature may exceed its desired operating range) because the fan that provides airflow to it is driven at too low a speed.

One solution to the above problems would be to provide the PSE with more temperature sensors arranged to sense temperatures of more components—in particular, providing a sensor to sense the temperature of the PSU—and adjust the fan speed control schemes to utilize these additional sensor inputs. But providing more temperature sensors for more components may not always be feasible. In particular, in some cases, the cost of providing additional temperature sensors in a PSE may be too high to be feasible, particularly for some components such as the PSU. While the individual sensor itself may not be very costly, integrating the sensor into the system may require a redesign of the system board layout and/or PSU board layout, and this can be quite costly. Thus, in some lower cost PSE devices, providing additional temperature sensors may not be feasible. In addition, existing PSE devices that lack the sensors may be difficult and costly to retrofit to include the sensors.

To address these and other issues, examples disclosed herein provide for controlling the rotational speed of one or more of the fan(s) of a PSE based at least in part on a measurement of PoE power usage (e.g., the amount of PoE power being provided by the PSE to, and consumed by, the PDs connected to the PSE). In some examples, the fans whose speed is controlled in this manner include at least the fan or fans that provide airflow through the PSU. In some examples, only the fan(s) that provide airflow through the PSU may be controlled based on the PoE power usage, while other fan(s) (if any are present) that provide airflow to other portions of the PSE may be controlled based on other control schemes (e.g., based on sensed temperatures). In other examples, all of the fans of the PSE may be controlled based, at least in part, on the PoE power usage.

Controlling the fan speed of one or more of the fan(s) based on PoE power usage as disclosed herein can allow PSE's that lack temperature sensors to nevertheless control their fan(s) intelligently and reduce their noise output while still providing adequate cooling. Moreover, the fan control described herein can allow PSE's that have temperature sensors to further improve the cooling performance of their fans and to avoid some of the difficulties noted above that can arise when using only temperature-based fan control. In particular, as noted above, controlling fans based solely on the sensed temperatures of certain components can lead to overprovisioning or under provisioning of airflow to the PSU because the amount of heat being generated by the PSU can be independent of the temperature sensed at other components. In contrast, the amount of heat generated by the PSU does depend on the amount of PoE power usage, and therefore controlling the speed of the fan(s) that cools the PSU based at least in part on the amount of PoE power usage better reflects the thermal conditions of the PSU and thus allows the fan speed to be set closer to the optimal speed.

Many existing PSE devices already are configured to determine the amount of PoE power being consumed by PDs. Moreover, even in devices that do not already determine this parameter, the functionality to sense this parameter can be added in a relatively cost-effective manner, often without requiring expensive redesign of the system or PSU board layout—for example, a shunt may be added to the PoE power rail to measure current flowing therethrough, with this current being indicative of the amount of PoE power being consumed. Accordingly, examples disclosed herein may implement the fan control at a lower cost than may be needed for the alternative approach of providing more temperature sensors in the device.

In some examples, the measured PoE power usage may be the sole parameter controlling the fan speed of at least the one or more fan(s) which provide(s) airflow through the PSU. For example, a fan controller may determine the fan speed of this fan by consulting a PoE power usage-based fan curve that comprises a function relating PoE power usage amounts to fan speeds. The PoE power usage-based fan curve may be similar in form to temperature-based fan curves, but instead of temperature being the independent variable in the curve, PoE power usage is the independent variable. In this manner, the fan speed of the fan(s) that supply airflow to the PSU are set based directly on the measured PoE power usage.

In some of the examples in which the fans that cool the PSU are controlled based solely on the PoE power usage parameter, the PSE may also comprise additional fans that provide airflow through other portions of the PSE, and these additional fans may be controlled based on other factors besides the PoE power usage parameter. For example, a fan that flows air over processing/control circuitry may be controlled based on a sensed temperature at the processing/control circuitry and using a temperature-based fan curve. In other words, in these examples, a PoE power usage-based fan control scheme is used for the fan(s) that flows air through the PSU while a different fan control scheme (e.g., a temperature based fan control scheme) may be used for the other fans of the PSE. In this manner, the differing thermal needs of the various components in the PSE can be taken into account when it comes to controlling the fans that cool these components, thus allowing each fan to be set to the speed that is optimal (or near thereto) for the particular components it cools. Thus, inadequate cooling of the components (particularly the PSU) and generation of unnecessary noise can be avoided or greatly reduced.

In some examples, rather than the PoE power usage parameter being the sole parameter that controls the speed of the one or more fans that flow air through the PSU, additional parameters may also be taken into account. In other words, in some examples, the fan speed of one or more of the fans may be controlled in part based on a measured PoE power usage amount and in part based on some other factor, such as a sensed temperature. This approach of using both the PoE power usage parameter and at least one other parameter to control the speed of the same fan may be referred to herein as hybrid fan control. Hybrid fan control may be particularly well suited to (but is not limited to) PSEs that have just one fan (which must cool both the PSU and the other components of the system) or that have multiple fans which are all driven at the same fan speeds, as the hybrid fan control can balance the potentially divergent cooling needs of these components by considering the different parameters that are indicative of their thermal conditions (e.g., PoE power usage for the PSU and sensed temperature for the processing/control circuitry). Thus, while the hybrid fan control might not always result in the fans being operated at a speed that is optimal for all of the components (because when only one fan is present or when all fans are operated at the same speed there may be no speed which is optimal for all components), the hybrid fan control scheme can reduce the likelihood of components being inadequately cooled and can reduce the magnitude of unnecessary noise generation as compared to purely temperature-based fan control.

Turning now to the figures, various devices, systems, and methods in accordance with aspects of the present disclosure will be described.

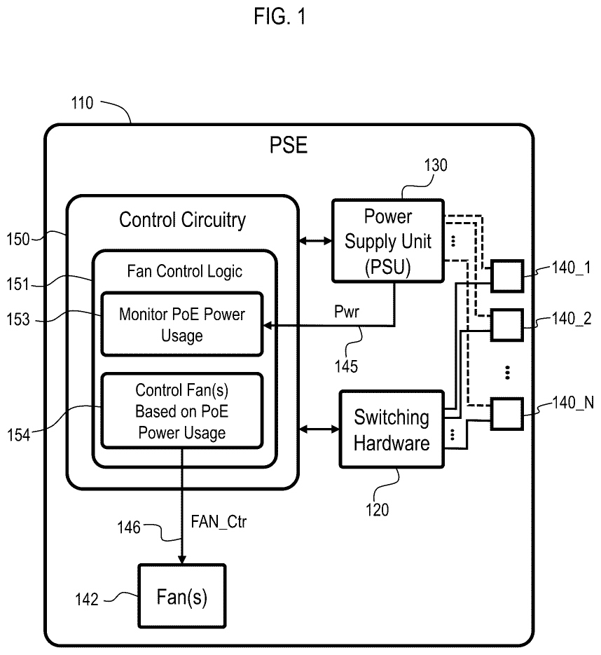

FIG. 1 is a block diagram conceptually illustrating an example PSE 110. The PSE 110 may, for example, be a switch, a router, an access point, or any other networking device that is configured to supply PoE power to connected PDs, as would be understood by those of ordinary skill in the art. Those of ordinary skill would understand that FIG. 1 is not intended to illustrate specific shapes, dimensions, or other structural details accurately or to scale. Moreover, the PSE 110 illustrated in FIG. 1 is one example and implementations of the PSE 110 may have different numbers and arrangements of the illustrated components and may also include other parts that are not illustrated.

As shown in FIG. 1, the PSE 110 comprises switching hardware 120, a power supply unit (PSU) 130, a plurality of ports 140 (three ports 140_1, 140_2, 140_N being shown in FIG. 1, collectively referred to as “ports 140”), control circuitry 150, and one or more fans 142 that are configured to provide an airflow through the PSE 110, for example, to cool one or more components of the PSE 110.

The switching hardware 120 comprises switching circuitry that can selectively connect the ports 140 to one another, thereby allowing for remote devices (not illustrated) coupled to the ports 140 to be communicably coupled together. The switching hardware 120 may also selectively connect the ports 140 to an uplink port to allow routing of data packets between an upstream device (e.g., switch) and the various remote devices connected to the ports 140 PSE 110. The switching hardware 120 may also have other related components that participate in, control, or otherwise facilitate the communication of the data packets. Switching hardware of a networking device is familiar to those of ordinary skill in the art, and thus the switching hardware 120 is not described in greater detail herein.

The power supply unit (PSU) 130 is configured to provide electrical power to the PSE 110 to run the functions of the PSE 110 itself, as well as provide PoE power to connected PDs via the ports 140. The PSU 130 may be controlled by the control circuitry 150 to control which of the ports 140 receive PoE power and/or to control amounts of PoE power allocated to the ports 140. The PSU 130 comprises one or more power supply devices that are configured to receive input power from a source, such as mains power or a power distribution unit, and convert that power into forms suitable for use by the PSE 110. The power supply devices of the PSU 130 may include an AC-to-DC converter, a DC-to-DC converter, protection devices (e.g., over-current protection, over-voltage protection, etc.), and/or other power components that participate in, control, or otherwise facilitate the supply of power to the PSE 110. PSUs of a networking device, such as, for example, a PSE are familiar to those of ordinary skill in the art, and thus the PSU 130 is not described in greater detail herein.

The ports 140 comprise RJ45 jacks configured to receive complimentary RJ45 connectors of an Ethernet cable to enable communication using one of the Ethernet family of protocols. Each port 140 is coupled to the control circuitry 150 (e.g., via the switching hardware 120) and is configured to communicate data between the control circuitry 150 and a remote device (e.g., a PD) connected to the port 140. At least some of the ports 140 may comprise PoE capable ports, meaning that the port 140 is configured to not only communicate data with a PD but also to supply PoE power to the PD via the same connector and cable. Each of the PoE capable ports 140 is also coupled to the PSU 130 and is configured to supply PoE power from the PSU 130 to the PD coupled to port 140 (unless PoE power has been disabled for the port 140 by the control circuitry 150). In FIG. 1 three ports (i.e., ports 140_1, 140_2, 140_N) are shown, but any number of ports 140 equal to or greater than one may be included in the PSE 110. Communication ports, including PoE ports, are familiar to those of ordinary skill in the art, and thus the ports 140 are not described in greater detail herein.

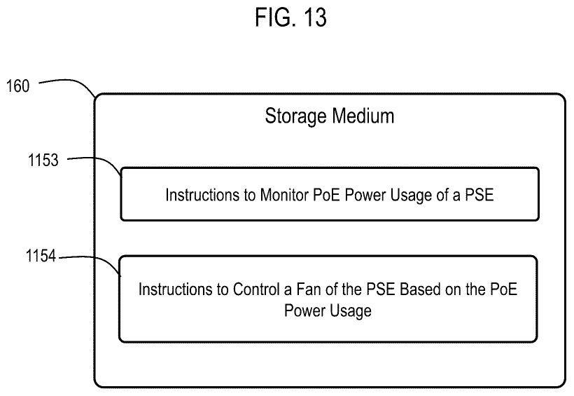

The control circuitry 150 comprises circuitry configured (e.g., programmed) to perform various operations that control the PSE 110. Among other things, the control circuitry 150 comprises fan control logic 151 to control the one or more fans 142 by performing, among other things, operations 153 and 154. As used herein, “logic” refers to dedicated hardware, software instructions stored in memory and coupled with a processor capable of executing the instructions, or some combination of these operations. Thus, in some examples the fan control logic 151 comprises a processor (not shown) and a storage medium (e.g., storage medium 160 in FIG. 13) storing instructions executable by the processor to cause operations 153 and 154 to be performed, in some examples the fan control logic 151 comprises dedicated hardware configured to perform operations 153 and 154, and in some examples the fan control logic 151 comprises some combination of the foregoing. The control circuitry 150 may also comprise a processor, which may be the same processor that is part of the fan control logic 151 or an additional processor, additional dedicated hardware, and/or some combination of these to perform the other operations of the control circuitry 150.

In examples in which the control circuitry 150 and/or fan control logic 151 comprise a processor, the processor may comprise one or more processing devices capable of executing machine readable instructions, such as, for example, a processor, a central processing unit (CPU), a controller, a microcontroller, a system-on-chip (SoC), a digital signal processor (DSP), a graphics processing unit (GPU), or other processing resources. In examples in which the control circuitry 150 includes dedicated hardware, in addition to or in lieu of the processor, the dedicated hardware may include any electronic device or logic circuit that is configured to perform specific operations, such as an Application Specific Integrated Circuit (ASIC), a Field Programmable Gate Array (FPGA), a Complex Programmable Logic Device (CPLD), discrete logic circuits, an analog circuit, a mixed control circuit, a hardware accelerator, a hardware encoder, etc.

In some examples, as will be described further below, the fan control logic 151 is configured to execute an operation 153 to monitor the amount of PoE power used or consumed by connected PDs (or in other words the amount of PoE power being supplied by the PSU). This may comprise monitoring a PoE power parameter 145, also be labeled herein as Pwr, which is a parameter that indicates the amount of PoE power being used (or which indicates another parameter from which the amount of PoE power usage can be derived). For example, in some implementations the PoE power parameter 145 comprises an analog electrical signal indicating an amount of current flowing through a common rail that supplies PoE power to the ports 140 (the current is indicative of the amount of PoE power being supplied). As another example, in some implementations the PoE power parameter 145 comprises a digital value indicating an amount of current flowing through the common rail that supplies PoE power to the ports 140. In some examples, the PoE power parameter 145 is measured and provided by the PSU to the control circuitry 150. In other examples, the fan control logic 151 may comprise circuitry to measure the PoE power parameter 145, such as a current sensor.

The fan control logic 151 is further configured to perform an operation 154 to control the fan speed of at least one of the one or more fans 142 based at least in part on the amount of PoE power usage, via fan control signals 146. To ease understanding, the description below will refer primarily to a single fan 142 when describing controlling fan speed based on the PoE power usage, but it should be understood that multiple fans 142 (in some cases, all of the fans 142) may have their speeds controlled in this manner. Moreover, in some examples the fan 142 (or fans 142) whose speed is controlled based on the PoE power usage comprise at least the fan 142 (or fans 142) that supplies airflow to the PSU 130. In some examples, an additional fan 142 (or fans 142) that supplies airflow to other components besides the PSU 130 may have their speed controlled based on something other than PoE power usage—for example, temperature-based fan control may be used for these other fans 142. In other examples, all of the fans 142 have their speeds controlled based at least in part on PoE power usage.

As part of controlling the fan speed of the fan 142 based on PoE power usage, the fan control logic 151 may determine set points for the rotational speed of the fan 142 and generate a fan control signal 146 that instructs or otherwise cause the fan 142 to rotate according to the determined set points. The fan control signal 146 may be, for example, pulse-width-modulation (PWM) signal. As would be familiar to those of ordinary skill in the art, a PWM signal comprises an analog electrical signal with repeating pulses wherein a duty cycle (pulse width) of the pulses is controlled so as to convey information, such as a fan speed set point in the case of fan control signals 146. Thus, the fan control logic 151 may determine a duty cycle for the fan control signal 146 that corresponds to the desired fan speed set point, and when the fan 142 receives the fan control signal 146 it may set its rotational speed according to the duty cycle thereof. Thus, in some examples the operation 154 described above of controlling the fan(s) 142 based at least in part on the PoE power usage may comprise setting the fan speed set point, and hence the duty cycle of the fan control signals 146, based at least in part on the PoE power usage.

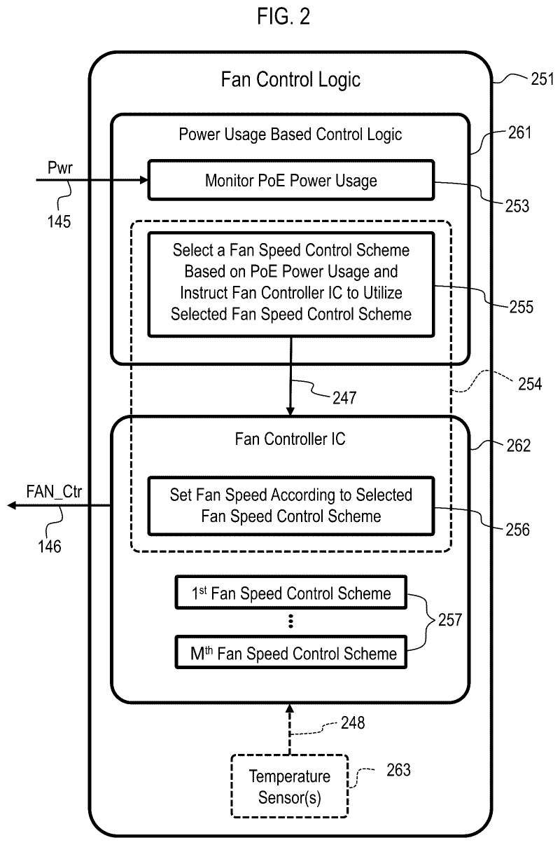

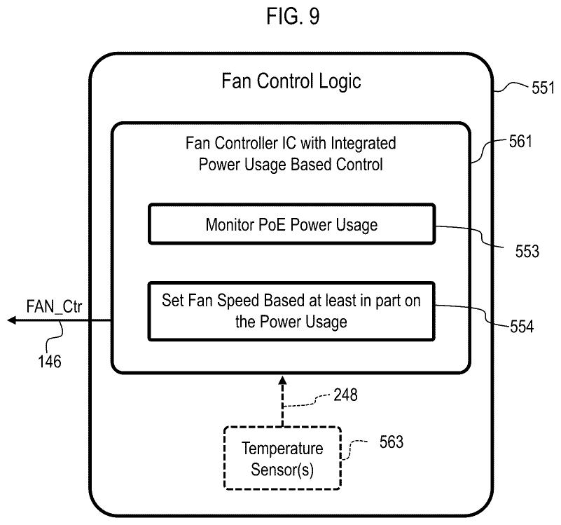

In some examples, operation 154 comprises setting the fan speed set point based directly on the PoE power usage, while in other examples, operation 154 comprises setting the fans speed set point based indirectly on the PoE power usage. For example, FIGS. 2-8, described in greater detail below, illustrate some examples in which the fan speed set point is based indirectly on the PoE power usage, whereas FIGS. 9-13, described in greater detail below, illustrate some examples in which the fan speed set point is based directly on the PoE power usage. In some examples in which the fan speed set point is based indirectly on the PoE power usage, predefined fan control schemes (e.g., a temperature based fan speed curve) may be used by the fan control logic 151 to directly control the fan speed set point based on some predefined parameter (e.g., temperature), and the fan control signals 146 may be used to determine which one of the fan control schemes is used, thus indirectly controlling (i.e., influencing) the fan speed set point.

In some implementations, the fan control logic 151 may comprise a fan controller that generates the fan control signals 146 and additional logic, separate from the fan controller, which monitors the PoE power usage signal 145 and performs other PoE power usage-based control operations. In other words, in these examples, aspects of the fan control that are related to PoE power usage may be performed by the logic external to the fan controller, and then the fan controller may determine the fan speed set point and the generate the fan speed control signal 146 based on inputs received from this external logic. FIG. 2 illustrates one such example, as will be described in greater detail below. In some other implementations, all aspects of operations 153 and 154 are integrated together into the same fan microcontroller. FIG. 9 illustrates one such example, as will be described in greater detail below.

In some examples, the fan controller that actually generates the fan control signals 146 may be formed from a commercially available fan controller which has been modified to perform operations as described herein, for example by modifying the firmware instructions thereof. Such modifications to the firmware instructions may be relatively inexpensive to implement, in some circumstances, especially when compared to the costs of redesigning the board layouts of the system board or PSU board as might be required to add additional temperature sensors. In examples that utilize logic external to the fan controller to perform the PoE power usage-based aspects of operations 153 and 154, relatively few modifications may be needed to the firmware instructions of the fan controller—for example, the firmware may be modified (if needed) to allow the fan controller to recognize the and follow the instructions sent from the external logic, such as the instructions specifying which control scheme to use. Moreover, in some cases, an already manufactured PSE upgraded or retrofitted to include the functionality described herein by reprogramming a fan microcontroller thereof.

In some examples, the control circuitry 150 may be configured to control other operations of the PSE 110 in addition to the operations 153 and 154, such as controlling operations of the switching hardware 120, operations of the PSU 130, security/authentication operations, and/or other operations of the PSE 110. In some examples, these functions are provided by portions of the control circuitry 150 other than the fan control logic 151, but these other portions are not illustrated or described in detail because they are familiar to those of ordinary skill in the art.

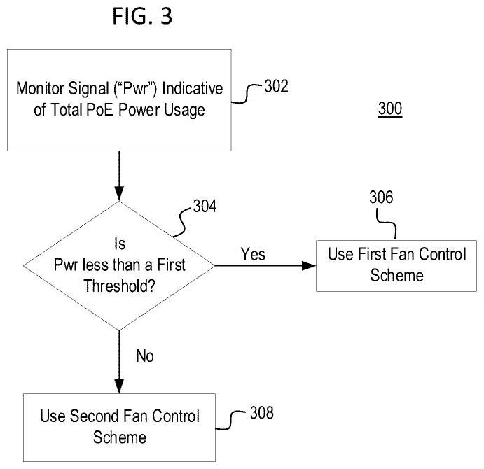

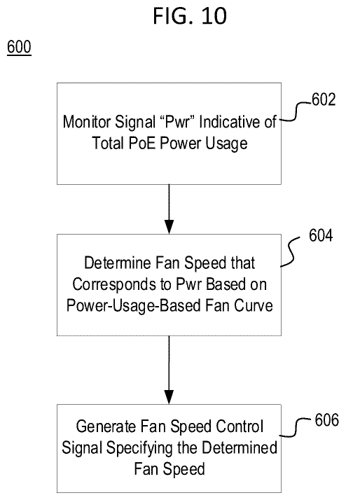

Turning now to FIGS. 2-13, various example configurations of the fan control logic 151 will be described. FIG. 2 illustrates fan control logic 251, which is one example configuration of fan control logic 151. FIGS. 3-8 illustrate various aspects of some example configurations of the fan control logic 251 and various example methods performable by fan control logic 251. FIG. 9 illustrates fan control logic 551, which is another example configuration of fan control logic 151. FIGS. 10-12 illustrate various aspects of an example configuration of the fan control logic 551 and an example method performable by the fan control logic 551.

Turning to FIG. 2, fan control logic 251 will be described. In this example, the fan control logic 251 comprises power usage-based control logic 261 and a fan controller IC 262. The fan control logic 216 is configured to perform operations 253 and 255. Operation 253 corresponds to operation 153 described above and comprises monitoring PoE power usage. Operation 255 comprises selecting a fan speed control scheme based on the PoE power usage. The fan control scheme may be selected from one of multiple fan control schemes 257 stored in (or accessible to) the fan controller IC 262. FIG. 2 illustrates M fan control schemes 257, where M is any integer equal to or greater than 2. These fan control schemes 257 may include, for example, temperature-based fan curves. For example, in some implementations the PoE power usage signal 145 is compared to one or more threshold values, and different fan control schemes 257 (e.g., temperature-based fan curves) may be selected depending on which threshold the PoE power usage signal 145 exceeds. In some implementations, the aggressiveness (e.g., slope) of the temperature-based fan curves may increase as the PoE power usage increases, resulting in greater airflow being provided to the PSU 130 when it is heavily loaded than would otherwise be provided at the same sensed temperature when the PSU 130 is lightly loaded. In some examples, one of the fan control schemes 257 may comprise the fans 142 being turned off or set to a fixed minimum value. In some examples, one of the fan control schemes 257 may comprise the fans 142 being set to a fixed maximum value. As another example, in some implementations the fan speed control schemes 257 may comprise both temperature-based fan curves and PoE power usage-based fan curves, and a temperature-based fan curve may be used when PoE power usage is below a certain threshold while a PoE power surge-based fan curve may be used if PoE power usage is above the threshold. The various examples of operation 255 described above may comprise examples of hybrid fan control as mentioned above.

Operation 255 also comprises instructing the fan controller IC 262 to utilize the selected fan speed control scheme, via sending signal 247 to the fan controller IC 262. The signal 247 may be a digital or analog signal that causes the fan controller IC 262 to utilize the selected fan control scheme.

The fan controller IC 262 is configured to produce the fan control signals 146 to set the airflows provided by the one or more fans 142 based on the selected fan speed control scheme, for example, based on one or more preloaded fan speed curves, as would be understood by those of ordinary skill in the art. In some examples, the fan control logic 151 comprises, or is communicably coupled with, one or more temperature sensors 262 that sense temperatures within PSE 110 and provide signal 248 indicative of the temperature to the fan controller IC 262, with the fan controller IC 262 generating the fan control signals 146 based at least in part on the signal 248. For example, as noted above, the fan controller IC 262 may utilize a fan speed curve that maps the sensed temperature to a fan speed set point. The temperatures sensor(s) 263 may, for example, be configured to sense the temperature of one or more portions of the control circuitry 150, such as a temperature of a processor thereof.

The selection of the fan control scheme in operation 255 and the generation of the fan control signals 146 by the fan controller IC 262 according to the selected fan control scheme in operation 256 together constitute a collective operation 254, which is one example implementation of the operation 154 described above in relation to FIG. 1. In other words, in this example implementation, operation 254 (which corresponds to operation 154) is performed in part by the power usage-based control logic 261 and in part by the fan controller IC 262. In some examples, the fan controller IC 262 may be a commercially available fan microcontroller that utilizes temperature based fan curves, as would be familiar to one of ordinary skill in the art, whereas power usage based control logic 261 may comprise logic separate and distinct from the fan controller IC 262, such as another microcontroller, a general purpose processor executing instructions, or other logic circuitry.

Turning now to FIG. 3, a method 300 will be described. Method 300 may be performed by fan control logic 151 or 251. Method 300 comprises steps corresponding to example implementations of operations 253 and 255 described above.

At block 302, the fan control logic monitors the PoE power signal Pwr indicative of the total PoE power usage.

At block 304, the fan control logic determines whether Pwr is less than a first threshold. If Pwr is less than a first threshold, the method continues to block 306. If Pwr is greater than the first threshold, the method continues to block 308. The condition of equality between Pwr and the first threshold may be treated arbitrarily as being a positive result or as a negative result, as desired according to the particular implementation. Thus, references herein to determinations of whether Pwr is less than or greater than a threshold do not necessarily imply anything about what happens on the condition of Pwr being equal to the threshold, unless explicitly indicated otherwise.

In block 306, the fan control logic selects a first fan control scheme for controlling the fans. In some examples, the first fan control scheme comprises the fans being turned off (or maintained in an off state if already off). In other examples, the first fan control scheme comprises a first temperature-based fan curve.

In block 308, the fan control logic selects a second fan control scheme for controlling the fans. The second fan control scheme is different from the first fan control scheme. In some examples, the second fan control scheme comprises a second temperature-based fan curve. In some examples, the second fan control scheme comprises a PoE power usage-based fan curve. In other examples, the second fan control scheme comprises a temperature power usage-based fan curve.

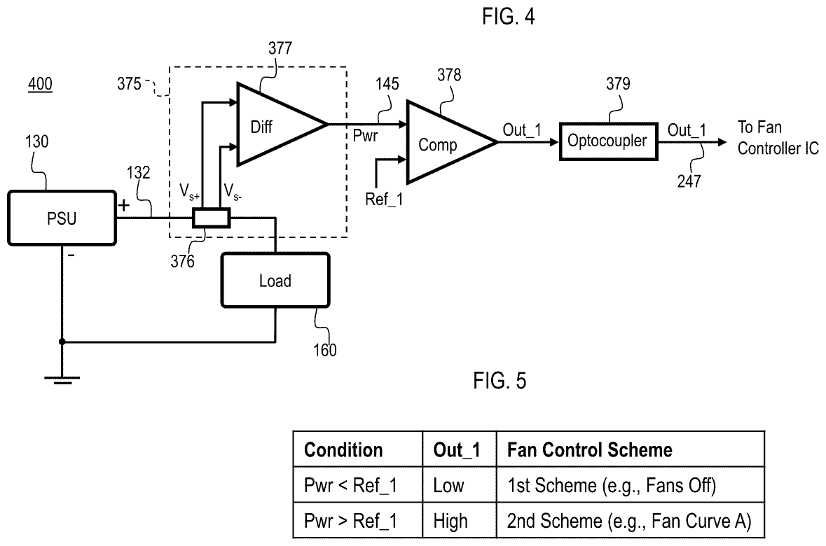

Turning now to FIG. 4, example circuitry 400 that may be used to implement aspects of the fan control logic 251 will be described. This circuitry 400 may be used, for example, to perform method 300 described above.

The circuitry 400 comprises a current sensor 375, which is coupled to a PoE power rail 132 of the PSU 130. The PoE power rail 132 is the rail which supplies PoE power to the ports 140 and then from ports 140 to any PDs coupled thereto. The ports 140 and the PDs connected thereto are referred to collectively as the load 160 in FIG. 4. The power rail 132 may be a DC power rail, and in some examples the current sensor 375 is coupled to the positive leg of the power rail 132 upstream of the load 160, as shown in FIG. 4. In other examples, the current sensor 375 is coupled to the return (ground) leg of the power rail 132 downstream of the load 160.

As shown in FIG. 4, in some examples the current sensor 375 comprises a shunt 376 which is disposed in the current path of the power rail 132 such that all current flowing from the PSU 130 to the load 160 passes through the shunt 376. The shunt 376 comprises a low resistance resistor with a precisely known resistance value, such that the voltage difference across the terminals thereof (i.e., Vₛ₊−Vₛ₋) is proportional to the current flowing through the shunt 736. Thus, by reading this voltage difference, the current can be sensed. The current sensor 375 may thus also comprise a voltage meter to determine the voltage difference Vₛ₊−Vₛ₋. In one example illustrated in FIG. 4, the voltage meter is a differential amplifier 377, and the terminals of the shunt 376 may be coupled to the inputs of the differential amplifier 377 so that the differential amplifier generates an analog output signal Pwr that has a voltage that is proportional to the voltage difference across the shunt's 735 terminals, i.e., proportional to Vₛ₊−Vₛ₋. This is merely one example of how a current sensor may be configured, and any type of current sensor may be used as current sensor 375. The current sensing performed by the current sensor 375 is one example of how the PoE power usage may be monitored per operations 153 or 253 in FIG. 1 or 2 or per step 302 of method 300 in FIG. 3.

The circuitry 400 further comprises a comparator 378_1. The comparator 378_1 receives the signal Pwr output by the current sensor 375 at one input and a reference voltage Ref_1 at another input. The comparator 378_1 compares Pwr to Ref_1, and outputs a binary voltage signal Out_1 based on the comparison. For example, Out_1 may have a high voltage if Pwr is greater than Ref_1 or a low voltage if Pwr is less than Ref_1. The comparison performed by the comparator 378_1 is one example of how the fan speed control scheme may be selected as per operation 255 of fan control logic 251 or as per steps 304 through 308 of method 300. Specifically, the reference voltage Ref_1 is one example of the “first threshold” of block 304 of method 300, and the comparison of Pwr to Ref_1 by the comparator corresponds to the determination made in block 304. The “yes” result of the determination in block 304 corresponds to the comparator determining that Pwr<Ref_1, whereas the “no” results result of the determination in block 304 corresponds to the comparator determining that Pwr>Ref_1.

The signal Out_1 may then be sent to the fan controller IC 262, with the signal Out_1 corresponding to the signal 247 described above that instructs the fan controller IC 262 which fan control scheme to use. That is, as shown in FIG. 5, the low voltage value of Out_1 may correspond to a first fan control scheme while the high voltage value of Out_1 may correspond to a second fan control scheme. Thus, the comparator 378_1 outputting the low voltage value for Out_1 may correspond to instructing the fan controller IC 262 to use the first fan control scheme as part of operation 255 of control logic 251 or block 306 of method 300, while the comparator 378_1 outputting the high voltage value for Out_1 may correspond to instructing the fan controller IC 262 to use the second fan control scheme as part of operation 255 of control logic 251 or block 306 of method 300. Accordingly, the fan controller IC 262 may know which of these fan control schemes to use based on the present voltage of Out_1. As conditions change, Out_1 may change and then the fan controller IC 262 may change which fan control scheme is used.

The cases of Pwr being equal to Ref_1 can be dealt with according to whatever voltage the comparator being utilized happens to output when this condition occurs. For example, if the comparator 378_1 outputs a “low” voltage when its inputs are equal, then the condition of Pwr=Ref_1 results in selection of the first fan control scheme, but if the comparator 378_1 outputs a “high” voltage when its inputs are equal, then Pwr=Ref_1 results in selection of the second fan control scheme.

As shown in FIG. 4, the signal Out_1 may be output to the fan controller IC 262 via an isolator/coupler 379, such as an optocoupler 379. The isolator/coupler 379 may be used to provide galvanic isolation between the power rail 132 and the fan controller IC 262.

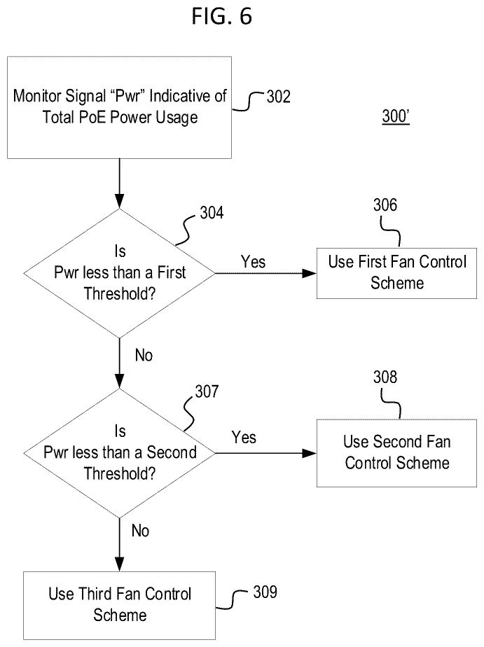

Turning now to FIG. 6, a method 300′ will be described. Method 300′ may be performed by fan control logic 151 or 251. Method 300′ comprises steps corresponding to example implementations of operations 253 and 255 described above. Method 300′ is a modification of the method 300 described above, and the method 300′ thus comprises some of the same steps as method 300.

Blocks 302, 304, and 306 have already been described above in relation to method 300. However, method 300′ differs from the method 300 in that, if in block 304 Pwr is greater than the first threshold, the method 300′ proceeds to block 307 (instead of proceeding to block 308 as occurred in the method 300). In block 307, Pwr is compared to a second threshold. If Pwr is less than the second threshold, the method 300′ continues to block 308, and the second fan control scheme is used. If Pwr is greater than the second threshold, then the method 300′ continues to block 309, and the third fan control scheme is used. As with the method 300, the condition of equality between Pwr and the first threshold or the second threshold may be treated arbitrarily as being a positive result or as a negative result in the determinations of blocks 304 or 307, as desired according to the particular implementation. Thus, references herein to determinations of whether Pwr is less than or greater than a threshold do not necessarily imply anything about what happens on the condition of Pwr being equal to the threshold, unless explicitly indicated otherwise.

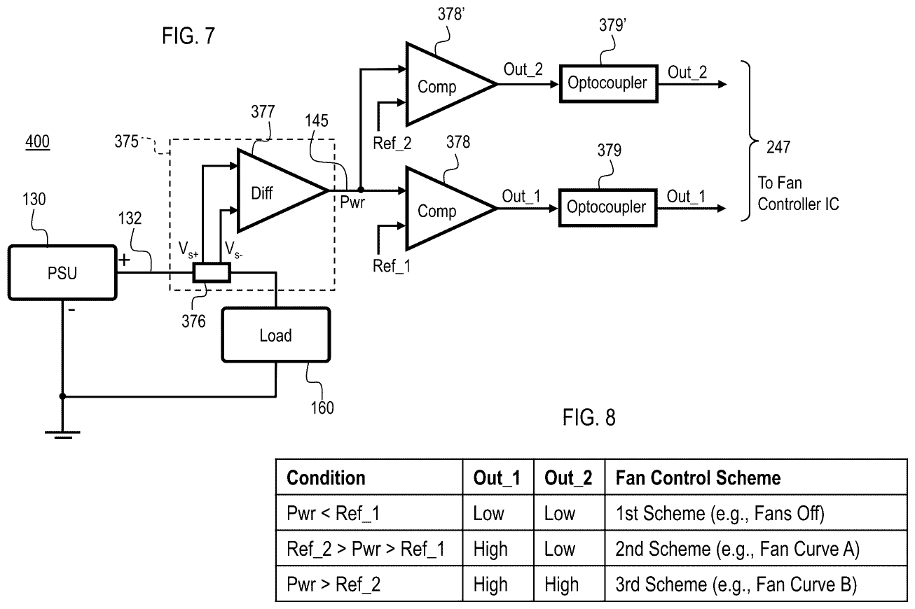

Turning now to FIG. 7, example circuitry 400′ that may be used to implement aspects of the fan control logic 251 will be described. This circuitry 400′ may be used, for example, to perform method 300′ described above. The circuitry 400′ is a modification of the circuitry 400 described above, and thus circuitry 400′ comprises some components which are similar or the same as components in circuitry 400. These same or similar components in circuitry 400′ are given the same references numerals as were used in relation to circuitry 400, and duplicative description thereof is omitted below.

The circuitry 400′ is similar to the circuitry 400 except that it includes an additional comparator 378_2. Similar to the comparator 378_1, the comparator 378_2 is configured to receive the signal Pwr at one input thereof and a reference voltage at the other input thereof and compare Pwr to the reference voltage. However, the comparator 378_2 differs from the comparator 378_1 in that the reference voltage provided to the comparator 378_2, i.e., Ref_2, is different from the reference voltage provided to the comparator 378_1, i.e., Ref_1. In some examples Ref_2>Ref_1. The comparator 378_2 outputs a signal Out_2 based on the comparison of Pwr to Ref_2. For example, Out_2 may have a high voltage if Pwr is greater than Ref_2 or a low voltage if Pwr is less than Ref_2.

The comparisons performed by the comparator 378_1 and the comparator 378_2 together form one example of how the fan speed control scheme may be selected as per operation 255 of fan control logic 251 or as per steps 304 through 309 of method 300′. Specifically, the comparison of Pwr to Ref_1 by the comparator 378_1 corresponds to the determination made in block 304 of method 300′, with the reference voltage Ref_1 being one example of the “first threshold”, and the comparison of Pwr to Ref_2 by the comparator 378_2 corresponds to the determination made in block 307 of method 300′, with the reference voltage Ref_2 being one example of the “second threshold.” In this example, the signal 247 comprises the combination of signals Out_1 and Out_2, and the fan control scheme that is indicated by the signal 247 may be encoded by the various combinations of voltage values that Out_1 and Out_2 can take. For example, as shown in FIG. 8, in one implementation if both Out_1 and Out_2 are low, this indicates selection of a first fan control scheme (which may be, for example, holding the fans in an off state). This result corresponds to block 306 of method 300′, which is reached when Pwr is less than the first threshold (i.e., Ref_1). Continuing this example, if Out_1 is high and Out_2 is low, this indicates selection of a second fan control scheme (which may be, for example, a first fan curve, titled Fan Curve A in FIG. 8). This result corresponds to block 308 of method 300′, which is reached when Pwr is greater than the first threshold (i.e., Ref_1) but less than the second threshold (i.e., Ref_2). Finally, in this example, if both Out_1 and Out_2 are high, this indicates selection of a third fan control scheme (which may be, for example, a second fan curve, titled Fan Curve B in FIG. 8). This result corresponds to block 309 of method 300′, which is reached when Pwr is greater than the second threshold (i.e., Ref_2).

The cases of Pwr being equal to Ref_1 or Ref_2 can be dealt with according to whatever voltage the comparators being utilized happen to output when this condition occurs. For example, if the comparator 378_1 outputs a “low” voltage when its inputs are equal, then the condition of Pwr=Ref_1 results in selection of the first fan control scheme, but if the comparator 378_1 outputs a “high” voltage when its inputs are equal, then Pwr=Ref_1 results in selection of the second fan control scheme.

As shown in FIG. 7, the signal Out_2 may be output to the fan controller IC 262 via an isolator/coupler 379′, such as an optocoupler 379′. The isolator/coupler 379′ may be used to provide galvanic isolation between the power rail 132 and the fan controller IC 262.

Method 300′ may be similar to method 300 in that in both of these methods a fan control scheme is selected out of a group of multiple fan control schemes based on comparison of Pwr to a set of thresholds. In method 300, the set of thresholds comprises one threshold (the first threshold) and the group of fan control schemes comprises two fan control schemes, whereas in method 300′ the set of thresholds comprises two thresholds (the first and second thresholds) and the group of fan control schemes comprises three fan control schemes. In other words, method 300′ comprises an example modification of method 300 in which an additional comparison is performed using an additional threshold, which allows for an additional fan control scheme to be included in the group of fan control schemes from which selection is made. It should be understood that the method 300′ can be modified in a like manner so as to include additional fan control schemes in the group of fan control schemes from which a selection is made. Specifically, the method 300′ may be modified to add one or additional determination blocks (analogous to determination block 307) to the existing chain of determination blocks in the method, in a similar fashion to how method 300′ was obtained by adding blocks 307 and 309 to method 300. Although not separately illustrated, each such modification of the method 300′ is contemplated herein as one of the disclosed example methods.

In other words, in some example methods disclosed herein (of which methods 300 and 300′ are but two examples), there is a chain of determination blocks analogous to block 307, and in each such determination block the signal Pwr is compared to a different threshold. For each determination block, the results of the determination lead to either selection of a corresponding fan control scheme or to the next determination block in the chain (except for the last determination block in the chain, for which both results of the determination lead to selection of different fan control schemes). In other words, examples disclosed herein comprise N determination blocks in the chain, wherein N thresholds are compared to Pwr to select between M fan control schemes (e.g., the M fan control schemes 257 illustrated in FIG. 2), where M=N+1. The example methods contemplated herein may include any number N of such determination blocks, wherein N is any integer equal to or greater than 1. Thus, method 300′ may be regarded as one example of the aforementioned example methods in which N=2 (and thus M=3) and method 300 may be regarded as one example of the aforementioned example methods in which N=1 (and thus M=2).

In a similar fashion to how example methods disclosed herein comprise any number N of determination blocks, example circuits disclosed herein for performing these methods may comprise any number N of comparators (analogous to comparators 378_1 and 378_2) to perform these determinations. In other words, in the same manner that circuitry 400′ is obtained by modifying the circuitry 400 to add the comparator 378_2, additional examples circuits contemplated herein may be obtained by adding additional comparators to circuitry 400′, wherein each additional comparator compares the signal Pwr to a different reference voltage and outputs a corresponding output signal. Thus, for example, a third comparator 378_3 may compare Pwr to a third reference voltage Ref_3 and output a third output signal Out_3, a fourth comparator 378_4 may compare Pwr to a fourth reference voltage Ref_4 and output a fourth output signal Out_4, and so on up to an Nth comparator 378_N which compares Pwr to an Nth reference voltage Ref_N and outputs an Nth output signal Out_N, wherein N is any integer equal to or greater than 1. In some examples, each successive reference voltage is greater than the previous reference voltage, i.e., Ref_1<Ref_2< . . . <Ref_N. Each different integer value of N corresponds to a different example circuit disclosed herein, and each of these circuits corresponds to and is configured to perform one of the example methods disclosed herein. For example, N=1 corresponds to the circuit 400, which performs the method 300; N=2 corresponds to the circuit 400′, which performs the method 300′, N=3 corresponds to another circuit (not illustrated) which is a modification of the circuit 400′ in which a third comparator 378_3 is added and which performs another method (not illustrated) in which another determination block is added following block 307 in method 300′, and so on for each integer value of N.

Turning now to FIG. 9, another example fan control logic 551 will be described. As noted above, fan control logic 551 is another example configuration of fan control logic 151.

The fan control logic comprises a fan controller integrated circuit (IC) 561 which has integrated therein PoE power usage-based fan control. In other words, the fan control logic 551 may differ from fan control logic 251 described above in that in the fan control logic 551 the PoE power usage-based aspects of the fan control operations are integrated together with the other aspects of fan control in the same single fan controller IC 561. In contrast, in fan control logic 251, the PoE power based aspects of the fan control, such as the selection of the fan control scheme based on the PoE power usage, were performed by logic that is not part of the fan controller IC 262, and the fan controller IC 262 instead merely performed fan control according to that selected fan control scheme in the manner that a fan microcontroller would normally perform fan control.

The fan controller IC 561 may comprise logic configured to perform operations 553 and 554. Operation 553 comprises monitoring PoE power usage, similar to operations 153 and 253. Operation 554 comprises setting the fan speed of one or more of the fans based at least in part on the PoE power usage parameter. In other words, in this example fan speed is set directly based on the PoE power usage. This is another difference between the fan control logic 551 and the fan control logic 251, as in the fan control logic 251 the speed of the fans is set indirectly based on the PoE power usage parameter in operation 254.

In some examples, setting the fan speed directly based on the PoE power usage in operation 554 may comprise consulting a PoE power usage-based fan curve. As described above, a PoE power usage-based fan curve may be similar in form to temperature-based fan curves, but instead of temperature being the independent variable in the curve, PoE power usage is the independent variable. The fan curve may be represented in a variety of forms, including a table that associates PoE power values with fan speeds, a mathematical equation that relates PoE power to fan speed, etc. The fan curve (of whatever format) may be used to determine a fan speed in view of a measured PoE power usage by finding which fan speed the fan curve maps the measured PoE power usage level to. In this manner, the PoE power usage-based fan curve is consulted and the fan speed of the fan(s) that supply airflow to the PSU are set based directly on the measured PoE power usage.

For example, if the PoE power usage-based fan curve is a table, then operation 554 may comprise searching the table based on the measured PoE power usage level to find a PoE power value stored in the table that is equal or closest to (rounding up, down, or to the nearest value, as desired) the measured value. The corresponding fan speed which is stored in the table in association with this PoE power usage level is then read out, and this fan speed is used by the fan controller IC 561 as the fan speed set point. The fan controller IC 561 then generates the fan control signal 146 based on the determined setpoint.

Or, as another example, if the PoE power usage-based fan curve is a mathematical equation, then operation 554 may comprise evaluating the equation with the measured PoE power usage value being input thereto as the value of the independent variable thereof. The resulting output of the equation is used by the fan controller IC 561 as the fan speed set point.

For example, FIG. 12 illustrates one example PoE power usage-based fan curve in graphical form. As shown in FIG. 12, this fan curve maps values of PoE power usage (labeled Pwr in FIG. 12) to fan speed. In this example, when Pwr′ is below a threshold P1, the fan speed is set to zero (i.e., the fans are off), when Pwr′ is above a threshold P2, the fan speed is set to a maximum value (e.g., a 100% PWM duty cycle), and when Pwr′ is between P1 and P2, the fan speed is varied linearly (proportional to Pwr′) between zero and the maximum value. This is but one example used for illustration, and the PoE power usage-based fan curves can take on any form, similar to how temperature-based fan curves can take on a variety of forms. Although the fan curve is illustrated in FIG. 12 as a continuous function, this need not be the case. For example, the fan curve could be represented as a finite collection of discrete points, as a step function, or in any desired form.

The PoE power usage-based fan curves may be determined in advance and stored in the fan controller IC 561. The PoE power usage-based fan curves may be determined experimentally. For example, one approach to determine the PoE power usage-based fan curves comprises running a test device at a variety of different PoE power usage levels, varying the fan speeds for each power usage level, observing the thermal conditions (e.g., temperatures) of the components of interest (e.g., the PSU), and noting which fan speeds produce the desired balance of cooling and noise for each of the PoE power levels. The tested power levels and the identified best fan speed for each may then be stored in a table, which forms the PoE power usage-based fan curve. As another example, the PoE power usage-based fan curves can be formed through modeling, wherein power levels and fan speeds are varied in a manner similar to that described above except in a computer/mathematical model rather than in a physical test device. In addition, portions of the PoE power usage-based fan curves can be formed through interpolation, extrapolation, or other statistical or analytical methods—for example, certain points of the fan curve may be determined experimentally for two power levels (e.g., in the manners described above) and then additional points of the fan curve may be determined for power levels in between these two power levels by interpolation from the experimentally determined results.

Once the fan speed set point is determined, the fan controller IC 561 may generate a fan control signal 146 (FAN_Ctr) and send this to one or more of the fans 142 to control their speed.

In some examples, the fan controller IC 561 may also control other fans 142 in the system based on parameters other than the PoE power usage. For example, in some implementations the fan 142 or fans 142 that cool the PSU may be controlled based on the PoE power usage, while one or more other fans 142 that cool other components may be controlled by the Fan controller IC 561 based on other parameters, such as sensed temperatures. For example, a fan 142 that cools the processing/control circuitry 150 may be controlled based on a sensed temperature thereof. Thus, in some examples, the fan control logic 551 comprises temperature sensors 563 to sense the temperatures of these other components. In other examples, an additional fan microcontroller may be used to control some of the fans 142—for example, the fan controller IC 561 may control the fans 142 that cool the PSU based on PoE power usage and another fan microcontroller (not illustrated) may control the other fans in the system using temperature-based fan control. In other examples, the fan controller IC 561 may control all the fans 142 based on PoE power usage.

In the description above, the fan controller IC 561 controls the fan speed based entirely on PoE power usage. But in some examples, the fan controller IC 561 may also consider other parameters. For example, in some implementations the PoE power consumption parameter (Pwr) may be combined with another parameter (such as a sensed temperature) to determine a combined parameter P_{combined}, and the combined parameter P_{combined} may be used to directly control the fan speed. The parameters may be combined through summing, averaging, or any other form of statistical combination. The parameters may also be normalized as part of the combination. For example, in one implementation P_{combined}=a·Pwr+b·T, where Pwr is the measured PoE power and T is the temperature, and a and b are constants used to normalize the values. Then in some examples a fan curve may be consulted that uses the combined parameter P_{combined} as the independent variable. As another example, in some implementations, the PoE power consumption parameter Pwr and another parameter, such as sensed temperature, may be used as separate independent variables in a multivariate (e.g., 3D) fan curve that maps different combinations of the multiple parameters to fan speeds.

The examples mentioned above in which Pwr and a sensed temperature are both considered when setting the fans speed (whether through combining the parameter or through a multivariate fan curve) may allow, for example, the fan speed to be set to a relatively high value if the PoE power usage is high, if the temperature is high, or if both are high. This can ensure that adequate cooling is always provided to both the PSU and the component whose temperature is sensed. Moreover, in these examples the fan speed may be set to a low value if both PoE power usage and temperature are low. This may ensure that unnecessary noise is reduced when high fan speed is not needed for cooling either the PSU or the component whose temperature is sensed. These approaches may be well suited to examples in which only a single fan is present, or in which multiple fans are present but all fans are driven at the same speed, as it can balance the potentially divergent needs of the different components (such as the PSU and the processor) as indicated by the different parameters. Other examples disclosed herein which control the fans separately based on separate parameters (e.g., controlling the fan that cools the PSU based on the PoE power usage and controlling the fan that cools the control circuitry based on a sensed temperature thereof) may be capable of even more reduction in unnecessary fan noise, but might not be feasible in some systems which have only one fan or which control their fans to all have the same fan speed.

FIG. 10 illustrates an example method 600 that may be performed by fan control logic 151 or 551. Method 600 comprises steps corresponding to example implementations of operations 553 and 555 described above.

At block 602, the fan control logic monitors the PoE power signal Pwr indicative of the total PoE power usage.

At block 604, the fan control logic determines a fan speed that corresponds to the measured Pwr based on a PoE power usage-based fan curve.

At block 606, the fan control logic generates a fan speed control signal specifying the determined fan speed. For example, the fan speed control signal may be a PWM signal and the duty cycle of the PWM signal may be set to reflect the fan speed identified in block 604.

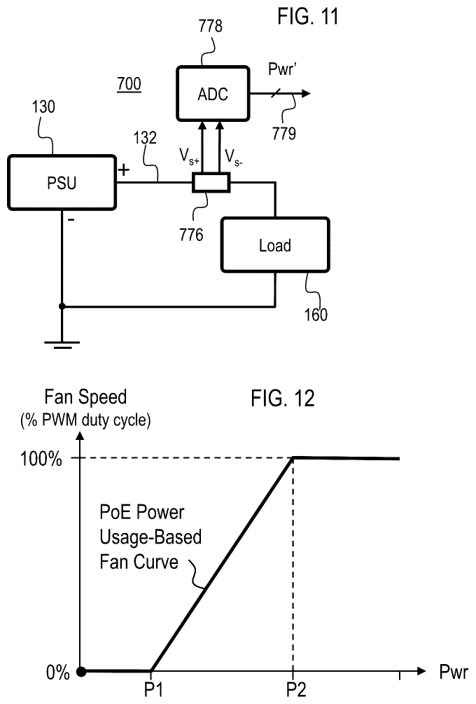

Turning now to FIG. 11, example circuitry 700 that may be used to implement aspects of the fan control logic 251 or 551 will be described. This circuitry 700 may be used, for example, to perform operations 302 or 602 of methods 300 or 600 described above. The example circuitry 700 is configured to monitor the PoE power usage. Like the circuitry 400 and 400′ described above, the circuitry 700 comprises a shunt 776 to sense the current flowing through rail 132. However, instead of using a voltage meter to determine an analog voltage difference Pwr and then comparing Pwr to N reference voltages using N comparators to obtain N analog output signals Out_1 to Out_N as occurs in circuitry 400 and 400′, in the circuit 700 the voltages Vₛ₊ and Vₛ₋ are fed into an analog-to-digital converter (ADC) 778 which determines the difference between Vₛ₊ and Vₛ₋ and converts that analog voltage difference into a digital value Pwr′, which is output as a digital signal 779. This digital value Pwr′ comprises a number that is proportional to the current flowing through rail 132, and thus Pwr′ is indicative of the amount of PoE power usage in a manner similar to how the analog signal Pwr was indicative of the amount of PoE power usage. Thus, this digital value Pwr′ can be used by downstream processing circuitry (such as a processor of the fan control logic 251 or 551) in place of the analog signal Pwr in any of the above-described operations that relate to PoE power usage. In other words, each of circuitry 400, 400′, and 700 monitors the PoE power usage and generates a signal representative thereof which is used in downstream processing operations, but the circuitry 700 generates a digital value Pwr′ representative of the PoE power usage, whereas circuitry 400 and 400′ generate analog signals Pwr representative of the PoE power usage.

As noted above, the fan control logic 251 and the fan control logic 551 differ from one another in two primary ways: first, whether functionality associated with operation 154 is integrated into a single fan controller IC (as in fan control logic 551) or is split between a fan controller IC and separate logic (as in fan control circuitry 251); and second, whether the fan speed is controlled directly based on the PoE power usage (as in fan control logic 551) or indirectly based on the PoE power usage (as in fan control logic 251). However, these two particular combinations of these features are illustrated and described as examples for convenience, but other combinations of these features are also contemplated herein.

For example, in one example of the fan control logic 151 (not illustrated), the functionality for operation 154 may be integrated into the same single fan controller IC in a manner similar to fan control logic 551, but that fan controller IC may control the fan speed based indirectly on the PoE power usage in a manner similar to fan control logic 251. For example, the fan controller IC may be configured to determine a fan control scheme based on the PoE power usage (similar to fan control logic 251) and then control the fan speed based on the selected fan control scheme.

As another example, in one example of the fan control logic 151 (not illustrated), the functionality for operation 154 may be split between a fan controller IC and separate logic a manner similar to fan control logic 251, but that fan controller IC may control the fan speed based directly on the PoE power usage in a manner similar to fan control logic 551. For example, the separate logic may be configured to determine a fan control scheme based on the PoE power usage (similar to fan control logic 251) and then the fan control IC may control the fan speed based on the selected fan control scheme, but one or more of the fan control schemes may include PoE power usage based fan curves that allow for the fan speed to be set based directly on the PoE power usage.

Turning now to FIG. 13, an example computer program product is described. The computer program product comprises a non-transitory compute readable storage medium 160 which stored instructions 1153 and 1154. These instructions 1153 and 1154 comprise computer instructions (e.g., software, firmware, etc.) that correspond to operations 153 and 154, respectively, meaning that instructions 1153 and 1154 are executable by a processor of the fan control logic 151 to cause the fan control logic 151 to perform operations 153 and 154, respectively. Thus, instructions 1153 comprise instructions to monitor the PoE power usage of the PSE, and instructions 1154 comprise instructions to control a speed of a fan of the PSE based at least in part on the PoE power usage. In some examples, fan control logic 151 comprises a processor and the storage medium 160, and is configured to perform operations 153 and 154 by virtue of the instructions 1153 and 1154 stored in the storage medium 160.

In the description above, various types of electronic circuitry are described. As used herein, “electronic” is intended to be understood broadly to include all types of circuitry utilizing electricity, including digital and analog circuitry, direct current (DC) and alternating current (AC) circuitry, and circuitry for converting electricity into another form of energy and circuitry for using electricity to perform other functions. In other words, as used herein there is no distinction between “electronic” circuitry and “electrical” circuitry.

It is to be understood that both the general description and the detailed description provide examples that are explanatory in nature and are intended to provide an understanding of the present disclosure without limiting the scope of the present disclosure. Various mechanical, compositional, structural, electronic, and operational changes may be made without departing from the scope of this description and the claims. In some instances, well-known circuits, structures, and techniques have not been shown or described in detail in order not to obscure the examples. Like numbers in two or more figures represent the same or similar elements.

In addition, the singular forms “a”, “an”, and “the” are intended to include the plural forms as well, unless the context indicates otherwise. Moreover, the terms “comprises”, “comprising”, “includes”, and the like specify the presence of stated features, steps, operations, elements, and/or components but do not preclude the presence or addition of one or more other features, steps, operations, elements, components, and/or groups. Components described as coupled may be electronically or mechanically directly coupled, or they may be indirectly coupled via one or more intermediate components, unless specifically noted otherwise. Mathematical and geometric terms are not necessarily intended to be used in accordance with their strict definitions unless the context of the description indicates otherwise, because a person having ordinary skill in the art would understand that, for example, a substantially similar element that functions in a substantially similar way could easily fall within the scope of a descriptive term even though the term also has a strict definition.

And/or: Occasionally the phrase “and/or” is used herein in conjunction with a list of items. This phrase means that any combination of items in the list—from a single item to all of the items and any permutation in between—may be included. Thus, for example, “A, B, and/or C” means “one of {A}, {B}, {C}, {A, B}, {A, C}, {C, B}, and {A, C, B}”.

Elements and their associated aspects that are described in detail with reference to one example may, whenever practical, be included in other examples in which they are not specifically shown or described. For example, if an element is described in detail with reference to one example and is not described with reference to a second example, the element may nevertheless be claimed as included in the second example.

Unless otherwise noted herein or implied by the context, when terms of approximation such as “substantially,” “approximately,” “about,” “around,” “roughly,” and the like, are used, this should be understood as meaning that mathematical exactitude is not required and that instead a range of variation is being referred to that includes but is not strictly limited to the stated value, property, or relationship. In particular, in addition to any ranges explicitly stated herein (if any), the range of variation implied by the usage of such a term of approximation includes at least any inconsequential variations and also those variations that are typical in the relevant art for the type of item in question due to manufacturing or other tolerances. In any case, the range of variation may include at least values that are within ±1% of the stated value, property, or relationship unless indicated otherwise.

Further modifications and alternative examples will be apparent to those of ordinary skill in the art in view of the disclosure herein. For example, the devices and methods may include additional components or steps that were omitted from the diagrams and description for clarity of operation. Accordingly, this description is to be construed as illustrative only and is for the purpose of teaching those skilled in the art the general manner of carrying out the present teachings. It is to be understood that the various examples shown and described herein are to be taken as exemplary. Elements and materials, and arrangements of those elements and materials, may be substituted for those illustrated and described herein, parts and processes may be reversed, and certain features of the present teachings may be utilized independently, all as would be apparent to one skilled in the art after having the benefit of the description herein. Changes may be made in the elements described herein without departing from the scope of the present teachings and following claims.

It is to be understood that the particular examples set forth herein are non-limiting, and modifications to structure, dimensions, materials, and methodologies may be made without departing from the scope of the present teachings.

Other examples in accordance with the present disclosure will be apparent to those skilled in the art from consideration of the specification and practice of the invention disclosed herein. It is intended that the specification and examples be considered as exemplary only, with the following claims being entitled to their fullest breadth, including equivalents, under the applicable law.

What is claimed is:

1. A power over ethernet (PoE) power sourcing equipment (PSE), comprising:
PoE ports connectable via respective communications links to powered devices (PDs);
a power supply unit (PSU) configured to supply PoE power to the PDs via the PoE ports and the communications links;
one or more fans configured to provide airflows through the PSE including at least a first fan configured to provide an airflow to the PSU; and
control circuitry comprising fan control logic configured to:
monitor a PoE power usage parameter indicative of an amount of the PoE power supplied by the PSU; and
control the speed of at least the first fan based at least in part on the PoE power usage parameter.

2. The PSE of claim 1, wherein the fan control logic is configured to control the speed of the first fan based directly on the PoE power usage parameter.

3. The PSE of claim 2, wherein the fan control logic is configured to determine a fan speed set point for the first fan based on a PoE power usage-based fan curve that maps PoE power usage values to fan speed values.

4. The PSE of claim 1, wherein the fan control logic is configured to control the speed of the first fan based in part on the PoE power usage parameter and in part on a sensed temperature.

5. The PSE of claim 1, wherein the fan control logic is configured to control the speed of the first fan based indirectly on the PoE power usage parameter.

6. The PSE of claim 5, wherein the fan control logic is configured to select a fan control scheme out of a plurality of fan control schemes based on the PoE power usage parameter and control the speed of the first fan based on the selected fan control scheme.

7. The PSE of claim 6, wherein the plurality of fan control schemes comprise at least one temperature-based fan curve.

8. The PSE of claim 7, wherein the plurality of fan control schemes comprise at least a first fan control scheme in which the fans are turned off.

9. The PSE of claim 7, wherein the plurality of fan control schemes comprise at least a first fan control scheme in which the fans are operated at maximum speed.

10. The PSE of claim 7, wherein the plurality of fan control schemes comprise a plurality of temperature-based fan curves.

11. The PSE of claim 6, wherein the fan control logic is configured to select the fan control scheme out of the plurality of fan control schemes by comparing the PoE power usage parameter to at least one threshold.

12. The PSE of claim 6,
wherein the fan control logic comprises:
a current sensor configured to generate a signal indicative of a current flowing through a PoE rail that carries the PoE power to the PoE ports; and
at least one comparator configured to compare the signal to a reference voltage, the output of the at least one comparator indicating the selected fan control scheme; and
a fan controller configured to receive the output of the at least one comparator and utilize the selected fan control scheme indicated by the output of the at least one comparator to control the speed of the first fan.

13. The device of claim 1, wherein the one or more fans comprise a second fan configured to provide an airflow to the control circuitry, and the fan control logic is configured to control the speed of the second fan based on a parameter other than the PoE power usage parameter.

14. The device of claim 1, wherein the one or more fans comprise a second fan configured to provide an airflow to the control circuitry, and the fan control logic is configured to control the speed of the second fan based at least in part on the PoE power usage parameter.

15. The device of claim 1, wherein the fan control logic is configured to control the speed of all of the one or more fans based at least in part on the PoE power usage parameter.

16. A method of cooling a power-over-Ethernet (PoE) power sourcing equipment (PSE), the method comprising:
monitoring a PoE power usage parameter indicative of an amount of PoE power supplied by a power supply unit (PSU) of the PSE to one or more powered devices (PDs) connected to the PSE; and
setting a speed of at least a first fan of the PSE based at least in part on the PoE power usage parameter.

17. The method of claim 17, wherein setting the speed of the first fan based at least in part on the PoE power usage parameter comprises selecting a fan control scheme out of a plurality of fan control schemes based on the PoE power usage parameter and controlling the speed of the fan based on the selected fan control scheme.

18. The method of claim 18, wherein selecting the fan control scheme comprises comparing the PoE power usage parameter to at least one threshold.

19. The method of claim 17, wherein setting the speed of the first fan based at least in part on the PoE power usage parameter comprises determining a fan speed set point for the first fan based on a PoE power usage-based fan curve that maps PoE power usage values to fan speed values.

20. A non-transitory computer readable medium storing instructions executable by a processor and configured to, when executed, cause the processor to:
monitor a PoE power usage parameter indicative of an amount of PoE power supplied by a power supply unit (PSU) of a PSE to one or more powered devices (PDs) connected to the PSE; and
set a speed of at least a first fan of the PSE based at least in part on the PoE power usage parameter.
